(19) United States
(12) Patent Application Publication
(10) Pub. No.: US 2020/0367360 A1
(43) Pub. Date: Nov. 19, 2020

(54) FLEXIBLE PRINTED WIRING BOARD

(71) Applicant: SUMITOMO ELECTRIC PRINTED CIRCUITS, INC., Shiga (JP)

(72) Inventors: Kousuke MIURA, Shiga (JP); Masahiko KOCHI, Shiga (JP)

(21) Appl. No.: 16/620,675

(22) PCT Filed: Jul. 3, 2018
(86) PCT No.: PCT/JP2018/025127

§ 371 Date: Dec. 9, 2019

(30) Foreign Application Priority Data
Jul. 6, 2017 (JP) 2017-133150

(51) Int. Cl. H05K 1/11; H01F 27/28

(52) U.S. Cl. CPC H05K 1/118; H01F 27/2804

(57) ABSTRACT

A flexible printed wiring board according to one embodiment of the present invention includes an insulating base film, a conductive pattern, laminated on at least a back surface side of the base film, and including a spiral coil pattern, and a plating layer, laminated on a back surface side of the conductive pattern, and formed by a ferromagnetic material. The conductive pattern may further include a coil core pattern that is formed on an inner side of an innermost periphery of the coil pattern.

### TECHNICAL FIELD

The present invention relates to a flexible printed wiring board. This application is based upon and claims priority to Japanese Patent Application No. 2017-133150, filed on Jul. 6, 2017, the entire contents of which are incorporated herein by reference.

### BACKGROUND ART

Recently, due to the spread of Radio Frequency Identification (RFID) systems, contactless IC cards, or the like utilizing the Near Field Communication (NFC) technique, devices that use a coil as an antenna are popularly utilized. Such a device is used as a wireless power supply device that includes a transformer in which a primary coil (feeding antenna) and a secondary coil (receiving antenna) are independently arranged, to make a contactless exchange of power.

In this wireless power supply device, the secondary coil is arranged at a position opposing the primary coil, to generate a current in the receiving antenna by a magnetic flux that is generated when a current is supplied to the feeding antenna. Such an antenna is about to become popularly used as a charging device for portable devices, for example, or the like.

The antenna for such portable devices is required to have a small size and be able to transmit power efficiently. However, when the antenna is formed by a coil using an enameled wire, a thickness of the coil inevitably needs to be increased in order to improve an inductance per unit area, and there is a limit to reducing the size of the antenna. In addition, when the number of turns of the coil is simply increased, a potential difference between one end and the other end of the coil becomes large, and a non-uniform magnetic field is generated, to deteriorate the efficiency of power exchange.

Accordingly, a proposal has been made to provide a spiral conductive pattern on a flexible printed wiring board, for use as the primary coil or the secondary coil of the wireless power supply device (refer to Japanese Laid-Open Patent Publication No. 2016-25163).

### PRIOR ART DOCUMENTS

### Patent Documents

Patent Document 1: Japanese Laid-Open Patent Publication No. 2016-25163

### DISCLOSURE OF THE INVENTION

### Means of Solving the Problem

A flexible printed wiring board according to one embodiment of the present invention includes an insulating base film, a conductive pattern, laminated on at least a back surface side of the base film, and including a spiral coil pattern, and a plating layer, laminated on a back surface side of the conductive pattern, and formed by a ferromagnetic material.

### BRIEF DESCRIPTION OF DRAWINGS

FIG. 1 is a schematic cross sectional view illustrating a structure of a flexible printed wiring board according to one embodiment of the present invention.

FIG. 2 is a schematic plan view of the flexible printed wiring board of FIG. 1.

FIG. 3 is a schematic cross sectional view illustrating the structure of the flexible printed wiring board according to an embodiment of the present invention different from that of FIG. 1.

FIG. 4 is a schematic plan view of the flexible printed wiring board of FIG. 3.

FIG. 5 is a schematic cross sectional view illustrating the structure of the flexible printed wiring board according to an embodiment of the present invention different from those of FIG. 1 and FIG. 3.

FIG. 6 is a schematic cross sectional view illustrating the structure of the flexible printed wiring board according to an embodiment of the present invention different from those of FIG. 1, FIG. 3, and FIG. 5.

FIG. 7 is a schematic cross sectional view illustrating the structure of the flexible printed wiring board according to an embodiment of the present invention different from those of FIG. 1, FIG. 3, FIG. 5, and FIG. 6.

### MODE OF CARRYING OUT THE INVENTION

### Problem to be Solved by the Invention

According to the coil formed on the flexible printed wiring board described in the above-mentioned publication, because the magnetic flux intersects 3-dimensionally by bending the coil, it is possible to improve a coupling coefficient of the primary coil and the second coil. However, the coil described in the above-mentioned publication is inconvenient in that a space provided for the bending tends to become large. Due to the further size reduction of the recent portable devices or the like, there are demands for a thin inductor that can generate a magnetic flux having a high density, so as to enable forming of the transformer that can efficiently exchange electrical signals and power while saving space.

Accordingly, the present invention is devised in view of the above circumstances, and it is one object of the present invention to provide a flexible printed wiring board that can generate a magnetic flux having a high density.

### Effects of Invention

The flexible printed wiring board according to one embodiment of the present invention can generate a magnetic flux having a high density.

### DESCRIPTION OF EMBODIMENTS OF PRESENT INVENTION

The flexible printed wiring board according to one embodiment of the present invention includes an insulating base film, a conductive pattern, laminated on at least a back surface side of the base film, and including a spiral coil pattern, and a plating layer, laminated on a back surface side of the conductive pattern, and formed by a ferromagnetic material.

Because the above-mentioned flexible printed wiring board includes the plating layer having ferromagnetic properties laminated on the back surface side of the conductive pattern that includes the spiral coil pattern, this plating layer guides a magnetic flux on the back surface side of the coil pattern to increase a magnetic flux density of a magnetic field that is formed on a front surface side.

In the flexible printed wiring board, the plating layer may be laminated directly on at least a part of the conductive pattern. By directly laminating the above-mentioned plating layer on the conductive pattern, it is possible to increase the magnetic flux density while reducing a thickness increase.

In the flexible printed wiring board, the conductive pattern may further include a coil core pattern that is formed on an inner side of an innermost periphery of the coil pattern. By including the coil core pattern in the above-mentioned conductive pattern, it is possible to guide the magnetic flux penetrating the coil pattern and increase the magnetic flux density.

In the flexible printed wiring board, the plating layer may be selectively laminated on the coil core pattern. By selectively laminating the above-mentioned plating layer on the coil core pattern, it is possible to increase an apparent permeability, and further increase the magnetic flux density.

The flexible printed wiring board may include a via hole connecting to the coil core pattern. In this case, when arranging a constituent element that guides the magnetic flux on a front surface side of the base film so as to overlap the coil core pattern in a plan view, it is possible to promote the effect of guiding the magnetic flux by integrating this constituent element and the coil core pattern.

### Detailed Description of Embodiments of Present Invention

The flexible printed wiring board according to each of the embodiments of the present invention will be described in detail, by referring to the drawings.

### First Embodiment

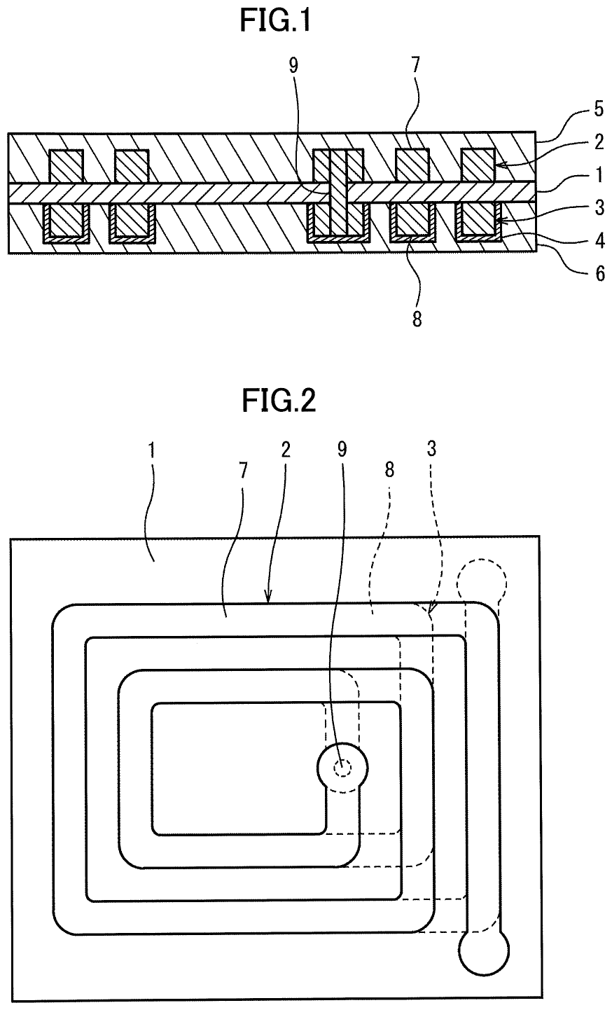

FIG. 1 and FIG. 2 illustrate the flexible printed wiring board according to a first embodiment of the present invention. The flexible printed wiring board includes an insulating base film 1, a first conductive pattern 2 laminated on a front surface side of the base film 1, a second conductive pattern 3 laminated on a back surface side of the base film 1, a patterned plating layer 4 formed by a ferromagnetic material and laminated directly on a back surface and side surfaces of the second conductive pattern 3, a first cover layer 5 covering front surfaces of the base film 1 and the first conductive pattern 2, and a second cover layer 6 covering back surfaces of the base film 1 and the second conductive pattern 3 having the patterned plating layer 4 laminated thereon.

The first conductive pattern 2 includes a first coil pattern 7 that is formed in a counter-clockwise spiral shape from an outer side in a plan view. On the other hand, the second conductive pattern 3 includes a second coil pattern 8 that is formed in a clockwise spiral shape from the outer side in a perspective plan view. The first coil pattern 7 and the second coil pattern 8 respectively are an approximately square-shaped spiral pattern that is formed by a plurality of linear parts that connect at right angles to each other.

Further, the flexible printed wiring board includes a coil connecting via hole 9 that is formed to penetrate the base film 1 and electrically connect the first conductive pattern 2 and the second conductive pattern 3. More particularly, the coil connecting via hole 9 is formed to connect an inner end part of the first coil pattern 7 and an inner end part of the second coil pattern 8. Hence, the first coil pattern 7 and the second coil pattern 8 form a single coil.

<Base Film>

The base film 1 is a base material that secures the strength of the flexible printed wiring board, and holds the first conductive pattern 2 and the second conductive pattern 3 in a state electrically isolated from each other.

A synthetic resin film that is formed to a sheet shape may be used for the base film 1. For example, polyimide, polyethylene terephthalate, liquid crystal polymer, fluororesin, or the like may preferably be used as a main component of this synthetic resin film. In addition, the base film 1 may include other resins, various additives, or the like, other than the main component. The main component refers to a component having a largest mass content, and preferably refers to a component having a mass content of 90% or higher.

A lower limit of an average thickness of the base film 1 is preferably 2.5 μm, and more preferably 5 μm. On the other hand, an upper limit of the average thickness of the base film 1 is preferably 50 μm, and more preferably 40 μm. When the average thickness of the base film 1 does not reach the above-mentioned lower limit, the insulating strength and the mechanical strength of the base film 1 may become insufficient. In addition, when the average thickness of the base film 1 exceeds the above-mentioned upper limit, a magnetic flux may be formed between the first coil pattern 7 and the second coil pattern 8 and decrease the magnetic flux formed on the front surface side of the flexible printed wiring board.

<Conductive Patterns>

The first conductive pattern 2 and the second conductive pattern 3 are formed by patterning a conductive material. This material forming the first conductive pattern 2 and the second conductive pattern 3 is preferably a metal such as copper, gold, silver, soft steel, stainless steel, aluminum, nickel, or the like, for example, and among these materials, copper is particularly preferable because of the relatively low cost and small electrical resistance.

The first coil pattern 7 of the first conductive pattern 2 and the second coil pattern 8 of the second conductive pattern 3 are formed so that the linear parts excluding the end parts overlap each other in the plan view, and have shapes of inverted mirror images about a straight line that is regarded as a center and passes through the end parts on the inner side.

A lower limit of an average thickness of the first conductive pattern 2 and the second conductive pattern 3 is preferably 0.1 μm, and more preferably 1 μm. On the other hand, an upper limit of the average thickness of the first conductive pattern 2 and the second conductive pattern 3 is preferably 300 μm, and more preferably 100 μm. When the average thickness of the first conductive pattern 2 and the second conductive pattern 3 does not reach the above-mentioned lower limit, an internal resistance may become large and a loss may become excessively large, and further, the strength may become insufficient and cause the first conductive pattern 2 and the second conductive pattern 3 to easily break. On the other hand, when the average thickness of the first conductive pattern 2 and the second conductive pattern 3 exceeds the above-mentioned upper limit, the flexible printed wiring board may become unnecessarily thick.

A lower limit of an average width of interconnections forming the first coil pattern 7 and the second coil pattern 8 is preferably 5 μm, and more preferably 10 μm. On the other hand, an upper limit of the average width of the interconnections foiling the first coil pattern 7 and the second coil pattern 8 is preferably 100 μm, and more preferably 50 μm. When the average width of the interconnections forming the first coil pattern 7 and the second coil pattern 8 does not reach the above-mentioned lower limit, the mechanical strength of the first coil pattern 7 and the second coil pattern 8 may become insufficient and break. On the other hand, when the average width of the interconnections forming the first coil pattern 7 and the second coil pattern 8 exceeds the above-mentioned upper limit, the first coil pattern 7 and the second coil pattern 8, and also the flexible printed wiring board, may become unnecessarily large. The average width of all of the interconnections forming the first coil pattern 7 and the second coil pattern 8 is preferably the same.

A lower limit of an average spacing (insulation distance) of the interconnections forming the first coil pattern 7 and the second coil pattern 8 is preferably 1 μm, and more preferably 2 μm. On the other hand, an upper limit of the average spacing of the interconnections forming the first coil pattern 7 and the second coil pattern 8 is preferably 30 μm, and more preferably 25 pin. When the average spacing of the interconnections forming the first coil pattern 7 and the second coil pattern 8 does not reach the above-mentioned lower limit, it may not be possible to positively prevent a short-circuit between the interconnections. On the other hand, when the average spacing of the interconnections forming the first coil pattern 7 and the second coil pattern 8 exceeds the above-mentioned upper limit, the first coil pattern 7 and the second coil pattern 8, and also the flexible printed wiring board, may become unnecessarily large.

<Patterned Plating Layer>

The patterned plating layer 4 captures the magnetic flux formed on the back surface side of the second coil pattern 8, and increases the density of the magnetic flux passing the inner side of the first coil pattern 7 and the second coil pattern 8 in the plan view, to increase the magnetic flux density of the magnetic field that is formed on the front surface side of the flexible printed wiring board.

The patterned plating layer 4 that is formed by the ferromagnetic material is laminated only on the second conductive pattern 3 on the back surface side, and is not laminated on the first conductive pattern 2 on the front surface side. Hence, the flexible printed wiring board does not include a constituent element that captures the magnetic flux at the front surface side, and thus, it is possible to form the magnetic field having a relatively large magnetic flux density up to a position that is separated from the flexible printed wiring board.

In addition, the patterned plating layer 4 is directly laminated on the second conductive pattern 3. By directly laminating the pattered plating layer 4 on the second conductive pattern 3, the patterned plating layer 4 can be formed by electroplating using the second conductive pattern 3 as an electrode.

For example, nickel, cobalt, chromium, iron, alloys of these elements, ferrite, or the like may be used for the ferromagnetic material forming the patterned plating layer 4.

A lower limit of an average thickness of the patterned plating layer 4 is preferably 0.1 μm, and more preferably 1.0 μm. On the other hand, an upper limit of the average thickness of the patterned plating layer 4 is preferably 100 μm, and more preferably 50 μm. When the average thickness of the patterned plating layer 4 does not reach the above-mentioned lower limit, it may not be possible to sufficiently capture the magnetic flux. On the other hand, when the average thickness of the patterned plating layer 4 exceeds the above-mentioned upper limit, the flexible printed wiring board may become unnecessarily thick, and the flexible printed wiring board may become unnecessarily expensive.

<Cover Layers>

The first cover layer 5 and the second cover layer 6 cover the first coil pattern 7 and the second coil pattern 8, to prevent breaks caused by a short-circuit inside the first coil pattern 7 and the second coil pattern 8, and the first coil pattern 7 and the second coil pattern 8 making contact with an external body.

The first cover layer 5 and the second cover layer 6 may have a single-layer structure of photosensitive solder resist or thermosetting solder resist, for example, and may alternatively have a multi-layer structure of a dry film solder resist including a base film and a resist layer, or a cover lay including a protection film and an insulating adhesive layer.

When the dry film solder resist is used for the first cover layer 5 and the second cover layer 6, a main component of the resist layer of the dry film solder resist may be epoxy resin, polyimide, and silicone resin, for example, and among these materials, epoxy resin, and particularly epoxy acrylate, may be preferably used. In addition, when the dry film solder resist is used, the base film may be polyimide or the like, for example.

A lower limit of an average thickness of the first cover layer 5 on the first coil pattern 7, and a lower limit of an average thickness of the second cover layer 6 on the second coil pattern 8, are preferably 3 μm, and more preferably 5 μm. On the other hand, an upper limit of the average thickness of the first cover layer 5 on the first coil pattern 7, and an upper limit of the average thickness of the second cover layer 6 on the second coil pattern 8, are not particularly limited, but are preferably 100 μm, and more preferably 50 μm. When the lower limit of the average thickness of the first cover layer 5 on the first coil pattern 7, and the lower limit of the average thickness of the second cover layer 6 on the second coil pattern 8, do not reach the above-mentioned lower limit, the insulation may become insufficient. On the other hand, when the upper limit of the average thickness of the first cover layer 5 on the first coil pattern 7, and the upper limit of the average thickness of the second cover layer 6 on the second coil pattern 8, exceed the above-mentioned upper limit, the flexibility of the flexible printed wiring board may become insufficient.

When the cover lay is used for the first cover layer 5 and the second cover layer 6, the above-mentioned protection film is preferably flexible and insulating. A main component of the protection film may be polyimide, epoxy resin, phenol resin, acrylic resin, polyester, thermoplastic polyimide, polyethylene terephthalate, fluororesin, liquid crystal polymer, or the like, for example. Particularly, polyimide is preferable from a viewpoint of heat resistance. The protection film may include other resins, antiweathering agents, antistatic agents, or the like, other than the main component.

A lower limit of an average thickness of the protection film is not particularly limited, but is preferably 3 μm, and more preferably 10 μm. On the other hand, an upper limit of the average thickness of the protection film is not particularly limited, but is preferably 500 μm, and more preferably 150 μm. When the average thickness of the protection film does not reach the above-mentioned lower limit, a break may easily be generated particularly during a manufacturing process. On the other hand, when the average thickness of the protection film exceeds the above-mentioned upper limit, the flexible printed wiring board may become unnecessarily thick.

An adhesive forming the above-mentioned adhesive layer is not particularly limited, but preferably has good flexibility and heat resistance. This adhesive may include various resin adhesive agents such as epoxy resin, polyimide, polyester, phenol resin, polyurethane, acrylic resin, melamine resin, polyamide-imide, or the like, for example.

A lower limit of an average thickness of the adhesive layer is preferably 5 μm, and more preferably 10 μm. On the other hand, an upper limit of the average thickness of the adhesive layer is preferably 50 μm, and more preferably 40 μm. When the average thickness of the adhesive layer does not reach the above-mentioned lower limit, the adhesive strength of the first cover layer 5 and the second cover layer 6 may become insufficient. On the other hand, when the average thickness of the adhesive layer exceeds the above-mentioned upper limit, the flexible printed wiring board may become unnecessarily thick.

<Coil Connecting Via Hole>

The coil connecting via hole 9 is formed by providing a conductor in a through hole that is foisted in the base film 1. The coil connecting via hole 9 may be made of a material similar to the material forming the first conductive pattern 2 and the second conductive pattern 3.

<Manufacturing Method>

The above-mentioned flexible printed wiring board may be manufactured by a method including a process that forms a thin conductive seed layer on the front surface and the back surface of the base film 1, a process that forms a through hole at a position of the base film 1 where the coil connecting via hole 9 is to be formed, and makes the through hole conductive, a process that forms a resist pattern having openings at positions where the first conductive pattern 2 and the second conductive pattern 3 are to be formed, a process that forms the first conductive pattern 2, the second conductive pattern 3, and the coil connecting via hole 9 by plating, a process that removes the resist pattern and the seed layer immediately below the resist pattern, a process that forms a resist layer covering the front surface of the base film 1 and the first conductive pattern 2, a process that laminates a ferromagnetic material on the second conductive pattern by plating, a process that removes the resist layer, and a process that laminates the first cover layer 5 and the second cover layer 6.

<Advantages>

Because the ferromagnetic pattern plating layer 4 is laminated on the back surface side of the second conductive pattern 3 in the above-mentioned flexible printed wiring board, this pattern plating layer 4 guides the magnetic flux that is formed on the back surface side of the second coil pattern 8, to increase the magnetic flux density on the back surface side and increase the magnetic flux density of the magnetic field formed on the front surface side.

### Second Embodiment

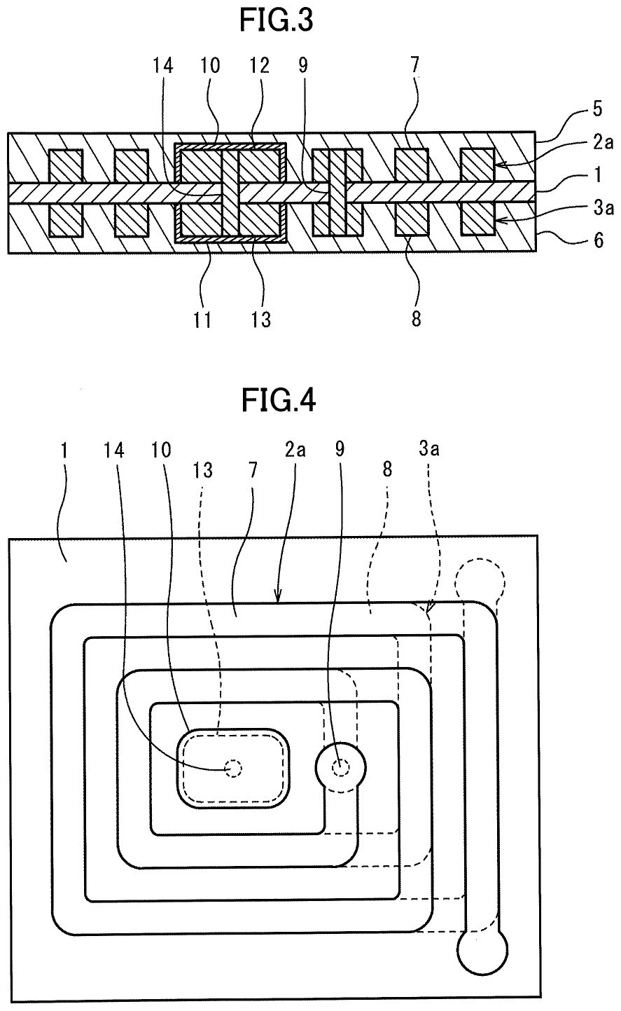

FIG. 3 and FIG. 4 illustrate the flexible printed wiring board according to an embodiment of the present invention different from that of FIG. 1 and FIG. 2. The flexible printed wiring board includes an insulating base film 1, a first conductive pattern 2a laminated on a front surface side of the base film 1, a second conductive pattern 3a laminated on a back surface side of the base film 1, a first plating layer 10 formed by a ferromagnetic material and laminated directly on a part of the front surface and side surfaces of the first conductive pattern 2a, a second plating layer 11 formed by a ferromagnetic material and laminated directly on a part of a back surface and side surfaces of the second conductive pattern 3a, a first cover layer 5 covering the base film 1 and the front surface of the first conductive pattern 2a having the first plating layer 10 laminated on a part thereof, and a second cover layer 6 covering the base film 1 and the back surface of the second conductive pattern 3a having the second plating layer 11 laminated on a part thereof.

The first conductive pattern 2a includes a first coil pattern 7 that is formed in a counter-clockwise spiral shape from an outer side in a plan view, and a first coil core pattern 12 that is formed on an inner side of an innermost periphery of the first coil pattern 7 in the plan view. On the other hand, the second conductive pattern 3a includes a second coil pattern 8 that is formed in a clockwise spiral shape from the outer side in a perspective plan view, and a second coil core pattern 13 that is formed on an inner side of an innermost periphery of the second coil pattern 8 in the perspective plan view.

Further, the flexible printed wiring board includes a coil connecting via hole 9 that is formed to penetrate the base film 1, the first conductive pattern 2a, and the second conductive pattern 3a, and electrically connects the first coil pattern 7 and the second coil pattern 8, and a coil core connecting via hole 14 that electrically connects the first coil core pattern 12 and the second coil core pattern 13.

The structures of the base film 1, the first cover layer 5, the second cover layer 6, the first coil pattern 7, the second coil pattern 8, and the coil connecting via hole 9 of the flexible printed wiring board of FIG. 3 are similar to the structures of the base film 1, the first cover layer 5, the second cover layer 6, the first coil pattern 7, the second coil pattern 8, and the coil connecting via hole 9 of the flexible printed wiring board of FIG. 1. For this reason, a repeated description of parts of the flexible printed wiring board of FIG. 3 that are the same as those of the flexible printed wiring board of FIG. 1 will be omitted.

<Conductive Patterns>

The first coil core pattern 12 of the first conductive pattern 2a, and the second coil core pattern 13 of the second conductive pattern 3a are formed to shapes that are approximately the same as each other, on the inner side of the first coil pattern 7 and the second coil pattern 8 in the plan view.

The first coil core pattern 12 and the second coil core pattern 13 become electrodes which will be described later and are used to form the first plating layer 10 and the second plating layer 11. In other words, the first coil core pattern 12 and the second coil core pattern 13 function as cores that increase the density of the magnetic flux penetrating the inner side of the first coil pattern 7 and the second coil pattern 8 in the plan view, by being covered by the first plating layer 10 and the second plating layer 11.

In addition, the first coil core pattern 12 and the second coil core pattern 13 are electrically connected to each other by the coil core connecting via hole 14. Hence, it is possible to promote the effect of guiding the magnetic flux by integrating the first coil core pattern 12 and the second coil core pattern 13, and further increase the magnetic flux density on the front surface side of the flexible printed wiring board.

<Plating Layers>

The first plating layer 10 is selectively laminated on the first coil core pattern 12, and the second plating layer 11 is selectively laminated on the second coil core pattern 13. Hence, the first coil core pattern 12 and the second coil core pattern 13 can both be made to function as a magnetic core.

<Coil Core Connecting Via Hole>

The coil core connecting via hole 14 may be similar to the coil connecting via hole 9.

<Manufacturing Method>

The above-mentioned flexible printed wiring board may be manufactured by a method including a process that forms a thin conductive seed layer on the front surface and the back surface of the base film 1, a process that forms through holes at positions of the base film 1 where the coil connecting via hole 9 and the core connecting via hole 14 are to be formed, and makes the through holes conductive, a process that forms a resist pattern having openings at positions where the first conductive pattern 2a and the second conductive pattern 3a are to be formed, a process that forms the first conductive pattern 2a, the second conductive pattern 3a, the coil connecting via hole 9, and the coil core connecting via hole 14 by plating, a process that removes the resist pattern and the seed layer immediately below the resist pattern, a process that forms a resist layer covering the first coil pattern 7 and exposing the first coil core pattern 12, and a resist layer covering the second coil pattern 8 and exposing the second coil core pattern 13, a process that laminates a ferromagnetic material on the first coil core pattern 12 and the second coil core pattern 13 exposed from the respective resist layers by plating, a process that removes the resist layers, and a process that laminates the first cover layer 5 and the second cover layer 6.

### Third Embodiment

FIG. 5 illustrates the flexible printed wiring board according to an embodiment of the present invention different from those of FIG. 1 and FIG. 3. The flexible printed wiring board includes an insulating base film 1, a first conductive pattern 2a laminated on a front surface side of the base film 1, a second conductive pattern 3a laminated on a back surface side of the base film 1, a first plating layer 10 formed by a ferromagnetic material and laminated directly on a part of the front surface and side surfaces of the first conductive pattern 2a, a second plating layer 11b formed by a ferromagnetic material and laminated directly on an entire back surface and side surfaces of the second conductive pattern 3a, a first cover layer 5 covering the base film 1 and the front surface of the first conductive pattern 2a having the first plating layer 10 laminated on a part thereof, and a second cover layer 6 covering the base film 1 and the back surface of the second conductive pattern 3a having the second plating layer 11b laminated thereon.

The first conductive pattern 2a includes a first coil pattern 7 that is formed in a counter-clockwise spiral shape from an outer side in a plan view, and a first coil core pattern 12 that is formed on an inner side of an innermost periphery of the first coil pattern 7 in the plan view. On the other hand, the second conductive pattern 3a includes a second coil pattern 8 that is formed in a clockwise spiral shape from the outer side in a perspective plan view, and a second coil core pattern 13 that is formed on an inner side of an innermost periphery of the second coil pattern 8 in the perspective plan view.

Further, the flexible printed wiring board includes a coil connecting via hole 9 that is formed to penetrate the base film 1, the first conductive pattern 2a, and the second conductive pattern 3a, and electrically connects the first coil pattern 7 and the second coil pattern 8, and a coil core connecting via hole 14 that electrically connects the first coil core pattern 12 and the second coil core pattern 13.

The structures of the base film 1, the first conductive pattern 2a, the second conductive pattern 3a, the first cover layer 5, the second cover layer 6, the first coil pattern 7, the second coil pattern 8, the coil connecting via hole 9, and the first plating layer 10 of the flexible printed wiring board of FIG. 5 are similar to the structures of the base film 1, the first conductive pattern 2a, the second conductive pattern 3a, the first cover layer 5, the second cover layer 6, the first coil pattern 7, the second coil pattern 8, the coil connecting via hole 9, and the first plating layer 10 of the flexible printed wiring board of FIG. 3. For this reason, a repeated description of parts of the flexible printed wiring board of FIG. 5 that are the same as those of the flexible printed wiring board of FIG. 3 will be omitted.

<Plating Layers>

The second plating layer 11b is laminated not only on the second coil core pattern 13, but also on the second coil pattern 8. Hence, the second plating layer 11b can function as a magnetic core together with the second coil core pattern 13, and guide the magnetic flux that is formed on the back surface side of the second coil pattern 8, to further increase the density of the magnetic flux passing through the second coil core pattern 13.

<Manufacturing Method>

The above-mentioned flexible printed wiring board may be manufactured by a method including a process that forms a thin conductive seed layer on the front surface and the back surface of the base film 1, a process that forms through holes at positions of the base film 1 where the coil connecting via hole 9 and the core connecting via hole 14 are to be formed, and makes the through holes conductive, a process that forms a resist pattern having openings at positions where the first conductive pattern 2a and the second conductive pattern 3a are to be formed, a process that forms the first conductive pattern 2a, the second conductive pattern 3a, the coil connecting via hole 9, and the coil core connecting via hole 14 by plating, a process that removes the resist pattern and the seed layer immediately below the resist pattern, a process that forms a resist layer covering the first coil pattern 7 and exposing the first coil core pattern 12, a process that laminates a ferromagnetic material on the first coil core pattern 12 exposed from the resist layer, the second coil core pattern 13, and the second conductive pattern 3a by plating, a process that removes the resist layer, and a process that laminates the first cover layer 5 and the second cover layer 6.

### Fourth Embodiment

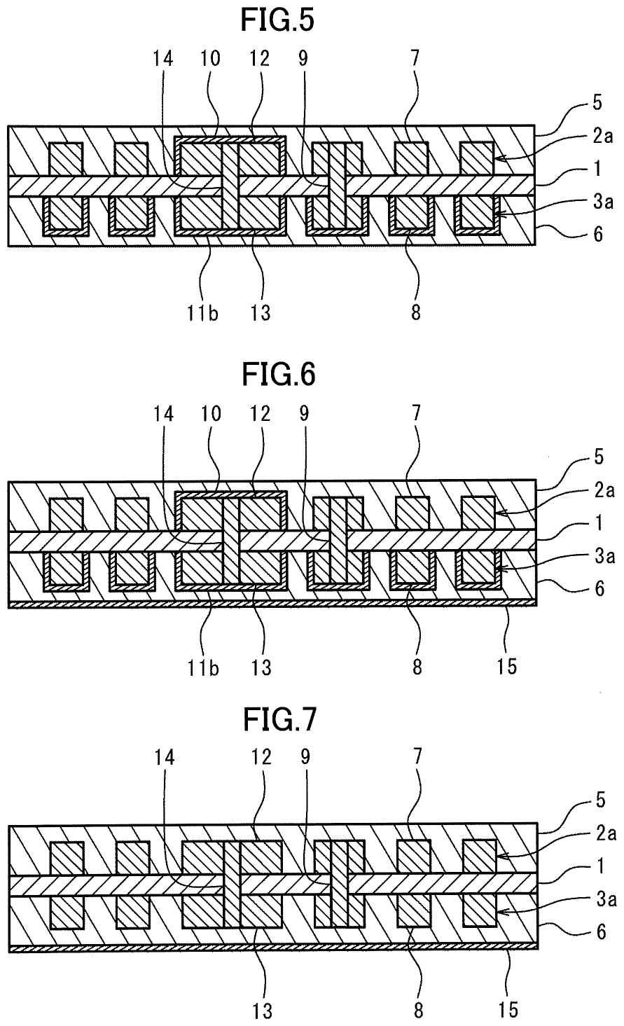

FIG. 6 illustrates the flexible printed wiring board according to an embodiment of the present invention different from those of FIG. 1, FIG. 3, and FIG. 5. The flexible printed wiring board includes an insulating base film 1, a first conductive pattern 2a laminated on a front surface side of the base film 1, a second conductive pattern 3a laminated on a back surface side of the base film 1, a first plating layer 10 formed by a ferromagnetic material and laminated directly on a part of the front surface and side surfaces of the first conductive pattern 2a, a second plating layer 11b formed by a ferromagnetic material and laminated directly on an entire back surface and side surfaces of the second conductive pattern 3a, a first cover layer 5 covering the base film 1 and the front surface of the first conductive pattern 2a having the first plating layer 10 laminated on a part thereof, a second cover layer 6 covering the base film 1 and the back surface of the second conductive pattern 3a having the second plating layer 11b laminated thereon, and a back surface plating layer 15 laminated on a back surface of the second cover layer 6.

The first conductive pattern 2a includes a first coil pattern 7 that is formed in a counter-clockwise spiral shape from an outer side in a plan view, and a first coil core pattern 12 that is formed on an inner side of an innermost periphery of the first coil pattern 7 in the plan view. On the other hand, the second conductive pattern 3a includes a second coil pattern 8 that is formed in a clockwise spiral shape from the outer side in a perspective plan view, and a second coil core pattern 13 that is formed on an inner side of an innermost periphery of the second coil pattern 8 in the perspective plan view.

Further, the flexible printed wiring board includes a coil connecting via hole 9 that is formed to penetrate the base film 1, the first conductive pattern 2a, and the second conductive pattern 3a, and electrically connects the first coil pattern 7 and the second coil pattern 8, and a coil core connecting via hole 14 that electrically connects the first coil core pattern 12 and the second coil core pattern 13.

The structures of the base film 1, the first conductive pattern 2a, the second conductive pattern 3a, the first cover layer 5, the second cover layer 6, the first plating layer 10, and the second plating layer 11b of the flexible printed wiring board of FIG. 6 are similar to the structures of the base film 1, the first conductive pattern 2a, the second conductive pattern 3a, the first cover layer 5, the second cover layer 6, the first plating layer 10, and the second plating layer 11b of the flexible printed wiring board of FIG. 5. For this reason, a repeated description of parts of the flexible printed wiring board of FIG. 6 that are the same as those of the flexible printed wiring board of FIG. 3 will be omitted.

<Back Surface Plating Layer>

The back surface plating layer 15 is formed by a ferromagnetic material, and is deposited on the entire back surface of the second cover layer 6. This back surface plating layer 15 guides the magnetic flux that is formed on the back surface side of the second coil pattern 8, to increase the density of the magnetic flux that turns back towards the front surface side.

In other words, because the flexible printed wiring board of FIG. 6 is further provided with the back surface plating layer 15 on the back surface side of the second plating layer 11b, it is possible to guide the magnetic flux that is formed on the back surface side of the second coil pattern 8, to increase the density of the magnetic flux that is turned back towards the front surface side, and form a magnetic field having a large magnetic flux density on the front surface side.

For example, nickel, cobalt, chromium, iron, alloys of these elements, or the like may be used for the ferromagnetic material forming the back surface plating layer 15.

A lower limit of an average thickness of the back surface plating layer 15 is preferably 0.1 μm, and more preferably 1.0 μm. On the other hand, an upper limit of the average thickness of the back surface plating layer 15 is preferably 50 μm, and more preferably 20 μm. When the average thickness of the back surface plating layer 15 does not reach the above-mentioned lower limit, it may not be possible to sufficiently capture the magnetic flux. On the other hand, when the average thickness of the back surface plating layer 15 exceeds the above-mentioned upper limit, the flexible printed wiring board may become unnecessarily thick, and the flexible printed wiring board may become unnecessarily expensive.

<Manufacturing Method>

The above-mentioned flexible printed wiring board may be manufactured by a method including a process that forms a thin conductive seed layer on the front surface and the back surface of the base film 1, a process that forms through holes at positions of the base film 1 where the coil connecting via hole 9 and the core connecting via hole 14 are to be formed, and makes the through holes conductive, a process that forms a resist pattern having openings at positions where the first conductive pattern 2a and the second conductive pattern 3a are to be formed, a process that forms the first conductive pattern 2a, the second conductive pattern 3a, the coil connecting via hole 9, and the coil core connecting via hole 14 by plating, a process that removes the resist pattern and the seed layer immediately below the resist pattern, a process that forms a resist layer covering the first coil pattern 7 and exposing the first coil core pattern 12, a process that laminates a ferromagnetic material on the first coil core pattern 12 exposed from the resist layer, the second coil core pattern 13, and the second conductive pattern 3a by plating, a process that removes the resist layer, a process that laminates the first cover layer 5 and the second cover layer 6, and a process that laminates a ferromagnetic material on the back surface of the second cover layer 6 by plating.

The above-mentioned process that laminates the ferromagnetic material may be performed by electroless plating, and the thickness of a ferromagnetic layer formed by the electroless plating may be increased by electroplating.

### Fifth Embodiment

FIG. 7 illustrates the flexible printed wiring board according to an embodiment of the present invention different from those of FIG. 1, FIG. 3, FIG. 5, and FIG. 6. The flexible printed wiring board includes an insulating base film 1, a first conductive pattern 2a laminated on a front surface side of the base film 1, a second conductive pattern 3a laminated on a back surface side of the base film 1, a first cover layer 5 covering the base film 1 and the front surface of the first conductive pattern 2a, a second cover layer 6 covering the base film 1 and the back surface of the second conductive pattern 3a, and a back surface plating layer 15 formed by a ferromagnetic material and laminated on a back surface of the second cover layer 6.

The first conductive pattern 2a includes a first coil pattern 7 that is formed in a counter-clockwise spiral shape from an outer side in a plan view, and a first coil core pattern 12 that is formed on an inner side of an innermost periphery of the first coil pattern 7 in the plan view. On the other hand, the second conductive pattern 3a includes a second coil pattern 8 that is formed in a clockwise spiral shape from the outer side in a perspective plan view, and a second coil core pattern 13 that is formed on an inner side of an innermost periphery of the second coil pattern 8 in the perspective plan view.

Further, the flexible printed wiring board includes a coil connecting via hole 9 that is formed to penetrate the base film 1, the first conductive pattern 2a, and the second conductive pattern 3a, and electrically connects the first coil pattern 7 and the second coil pattern 8, and a coil core connecting via hole 14 that electrically connects the first coil core pattern 12 and the second coil core pattern 13.

The structures of the base film 1, the first conductive pattern 2a, the second conductive pattern 3a, the first cover layer 5, the second cover layer 6, the coil connecting via hole 9, and the coil core via hole 14 of the flexible printed wiring board of FIG. 7 are similar to the structures of the base film 1, the first conductive pattern 2a, the second conductive pattern 3a, the first cover layer 5, the second cover layer 6, the coil connecting via hole 9, and the coil core connecting via hole 14 of the flexible printed wiring board of FIG. 3. In addition, the structure of the back surface plating layer 15 of the flexible printed wiring board of FIG. 7 is similar to the structure of the back surface plated layer 15 of the flexible printed wiring board of FIG. 6. For this reason, a repeated description of parts of the flexible printed wiring board of FIG. 7 that are the same as those of the flexible printed wiring board of FIG. 3, or the flexible printed wiring board of FIG. 7, will be omitted.

<Manufacturing Method>

The above-mentioned flexible printed wiring board may be manufactured by a method including a process that forms a thin conductive seed layer on the front surface and the back surface of the base film 1, a process that forms through holes at positions of the base film 1 where the coil connecting via hole 9 and the core connecting via hole 14 are to be formed, and makes the through holes conductive, a process that forms a resist pattern having openings at positions where the first conductive pattern 2a and the second conductive pattern 3a are to be formed, a process that forms the first conductive pattern 2a, the second conductive pattern 3a, the coil connecting via hole 9, and the coil core connecting via hole 14 by plating, a process that laminates the first cover layer 5 and the second cover layer 6, and a process that laminates a ferromagnetic material on the back surface of the second cover layer 6 by plating.

### Other Embodiments

The present invention is not limited to the examples of embodiments disclosed above. The scope of the present invention is not limited the structure of the above-mentioned embodiments, and is intended to include all modifications within the meaning and scope of the claims presented and equivalents thereof.

The above-mentioned flexible printed wiring boards are not limited to those manufactured by the manufacturing methods of the embodiments described above. For example, the via hole of the flexible printed wiring boards may be formed by a process that forms a through hole penetrating the base film and the conductive pattern, after forming the conductive pattern, and makes the through hole conductive.

The above-mentioned flexible printed wiring boards may be formed with the conductive pattern only on one surface side of the base film. In addition, the above-mentioned flexible printed wiring boards may include 2 or more base films and 3 or more layers of conductive patterns, and a plating layer formed by a ferromagnetic material may be formed on a back surface side of the conductive pattern located on the most back surface side.

In the above-mentioned flexible printed wiring boards, the coil core patterns on the front and back surfaces of the base film do not need to be electrically connected by the via hole.

### DESCRIPTION OF THE REFERENCE NUMERALS

1 Base Film
2, 2a First Conductive Pattern
3, 3a Second Conductive Pattern
4 Patterned Plating Layer
5 First Cover Layer
6 Second Cover Layer
7 First Coil Pattern
8 Second Coil Pattern
9 Coil Connecting Via Hole
10 First Plating Layer
11, 11b Second Plating Layer
12 First Coil Core Pattern
13 Second Coil Core Pattern
14 Coil Core Connecting Via Hole
15 Back Surface Plating Layer

1. A flexible printed wiring board comprising:
an insulating base film;
a conductive pattern, laminated on at least a back surface side of the base film, and including a spiral coil pattern; and
a plating layer, laminated on a back surface side of the conductive pattern, and formed by a ferromagnetic material.

2. The flexible printed wiring board as claimed in claim 1, wherein the plating layer is laminated directly on at least a part of the conductive pattern.

3. The flexible printed wiring board as claimed in claim 1, wherein the conductive pattern further includes a coil core pattern that is formed on an inner side of an innermost periphery of the coil pattern.

4. The flexible printed wiring board as claimed in claim 3, wherein the plating layer is selectively laminated on the coil core pattern.

5. The flexible printed wiring board as claimed in claim 3, further comprising:
a via hole connecting to the coil core pattern.

6. The flexible printed wiring board as claimed in claim 2, wherein the conductive pattern further includes a coil core pattern that is formed on an inner side of an innermost periphery of the coil pattern.

7. The flexible printed wiring board as claimed in claim 6, wherein the plating layer is selectively laminated on the coil core pattern.

8. The flexible printed wiring board as claimed in claim 4, further comprising:
a via hole connecting to the coil core pattern.
